(19) United States
(12) Patent Application Publication
(10) Pub. No.: US 2021/0088661 A1
(43) Pub. Date: Mar. 25, 2021

(54) PHOTODETECTOR AND OPTICAL RANGING APPARATUS USING THE SAME

(71) Applicant: DENSO CORPORATION, Kariya-city (JP)

(72) Inventors: Takehiro HATA, Kariya-city (JP); Kenta AZUMA, Kariya-city (JP); Hiroyuki MATSUBARA, Nagakute-shi (JP); Isamu TAKAI, Nagakute-shi (JP)

(21) Appl. No.: 16/952,616

(22) Filed: Nov. 19, 2020

Related U.S. Application Data
(63) Continuation of application No. PCT/JP2019/020703, filed on May 24, 2019.

(30) Foreign Application Priority Data
May 24, 2018 (JP) 2018-099419

(51) Int. Cl. G01S 17/14; G01S 7/481; G01S 7/4863

(52) U.S. Cl. CPC G01S 17/14; G01S 7/4863; G01S 7/4816

(57) ABSTRACT

A photodetector and an optical ranging apparatus provided with the photodetector are disclosed. The photodetector includes a pulse output section that changes an output from a light-receiving element to a rectangular pulse having a predetermined pulse width and outputs the rectangular pulse. Further, the photodetector also includes a pulse conversion circuit that converts the rectangular pulse to a rectangular pulse having a pulse width different from the predetermined pulse, based on the rise and fall of the rectangular pulse.

### CROSS-REFERENCE TO RELATED APPLICATION

The present application claims the benefit of priority from earlier Japanese Patent Application No. 2018-99419 filed on May 24, 2018, the entire description of which is incorporated herein by reference.

### BACKGROUND

The present disclosure relates to a photodetector and an optical ranging apparatus using the same.

### SUMMARY

In the present disclosure, provided a photodetector including a pulse output section and a pulse conversion circuit.

### BRIEF DESCRIPTION OF THE DRAWINGS

In the accompanying drawings:

FIG. 1A is a diagram illustrating a configuration of a photodetector according to an embodiment of the present disclosure.

FIG. 1B is a diagram illustrating a configuration of an optical ranging apparatus according to an embodiment of the present disclosure.

FIG. 2 is a diagram illustrating a configuration example of a photodetector according to an embodiment of the present disclosure.

FIG. 3 is a diagram illustrating a configuration of a discriminator according to a first embodiment.

FIG. 4A is a timing diagram illustrating operation of the photodetector according to the first embodiment.

FIG. 4B is a timing diagram illustrating operation of a photodetector according to a modification of the first embodiment.

FIG. 5 is a diagram illustrating a configuration of a discriminator according to a second embodiment.

FIG. 6 is a timing diagram illustrating operation of a photodetector according to the second embodiment.

FIG. 7 is a diagram illustrating a configuration of a discriminator according to a comparative example.

FIG. 8 is a timing diagram illustrating operation of a photodetector according to a comparative example.

FIG. 9 is a diagram illustrating calculation results in terms of signal to noise ratio (SNR), for the photodetectors of the first and second embodiments and the comparative embodiment.

FIG. 10 is a diagram illustrating calculation results in terms of signal to noise ratio (SNR), for the photodetectors of the first and second embodiments and the comparative example.

### DETAILED DESCRIPTION OF THE PREFERRED EMBODIMENTS

Avalanche photo diodes (APDs) are used as light-receiving elements for detecting weak optical signals in the fields of optical communication and optical radar, and in other fields. When photons are incident on APDs, electron-hole pairs are generated. The electrons and holes in these pairs are individually accelerated in a high electric field, causing collision and ionization one after another like an avalanche, and finally generate new electron-hole pairs.

As modes of using APDs, a linear mode and a Geiger mode are available. In the linear mode, a reverse bias voltage is activated at a level below a breakdown voltage. In the Geiger mode, a reverse bias voltage is activated at a level of not less than a breakdown voltage. In the linear mode, the percentage of disappearing electron-hole pairs (electron-hole pairs emitted from the high electric field) is higher than the percentage of the generated electron-hole pairs. Therefore, the avalanche phenomenon stops naturally. Current outputted from APDs due to the avalanche phenomenon (avalanche current) is substantially in proportion to the intensity of incident light, and thus can be used for measuring the intensity of incident light. In the Geiger mode, incidence of even one photon can cause an avalanche phenomenon. Such a photodiode is referred to as a single photon photodiode (single photon avalanche diode (SPAD)).

SPADs can reduce the applied voltage to a level below the breakdown voltage to stop the occurrence of an avalanche phenomenon. Stopping the occurrence of an avalanche phenomenon by reducing the applied voltage is referred to as quenching. A simplest quenching circuit is achieved by connecting an APD in series with a quenching resistor. When avalanche current is generated, the voltage between the terminals of the quenching resistor increases. As a result, the bias voltage of the APD decreases and when the bias voltage drops to a level below the breakdown voltage, the avalanche current will stop. APDs, to which a high electric field can be applied, can quickly respond to faint light and thus are widely used in the fields of optical ranging devices, optical communication, and the like.

Patent Literature 1 (JP 2012-60012 A) discloses a photodetector that includes a discriminator which converts an output signal from an APD to a rectangular pulse. Non-Patent Literature 1 (“Silicon photomultiplier and its possible application”, Nuclear Inst & Methods in Physics Research, 2003, 504(1-3), pp 48-52) discloses a silicon photomultiplier which is an array of a plurality of APDs used in a Geiger mode.

Photodetectors based on conventional art, such as photodetectors including SAPDs mentioned above, detect photons, for example, which are incident from a light source, and output signals corresponding to the detected photons, as pulses shaped with a fixed length. Such photodetectors count the pulses that have been shaped with a fixed length to thereby count the incident photons.

If a specific photon is detected, some photodetectors of conventional art may require a predetermined period, i.e., a lapse of dead time, before detecting the subsequent photon. In the photodetectors of conventional art that produce such dead time, if a new photon is incident during the dead time produced by detecting the previously incident photon, one long pulse is outputted regardless of the entry of the new photon. Therefore, the photodetectors of conventional art have a probability that incident photons cannot be correctly counted.

The present disclosure provides a photodetector that can correctly count photons which are incident substantially simultaneously (incident within a predetermined period).

A first aspect of the present embodiment is a photodetector including a pulse output section and a pulse conversion circuit. The pulse output section outputs an output from a light-receiving element as a first rectangular pulse having a predetermined pulse width. The pulse conversion circuit converts the first rectangular pulse to a second rectangular pulse having a pulse width different from the predetermined pulse width, the second rectangular pulse being based on rise of the first rectangular pulse and fall of the first rectangular pulse.

A second aspect of the present disclosure is a photodetector including an array that includes a plurality of light-receiving elements; a plurality of discriminators that convert output signals from the respective plurality of light-receiving elements to shaped rectangular pulses; and an adder circuit that adds up the shaped rectangular pulses outputted from the plurality of discriminators and outputs an obtained added-up signal. In the photodetector, each of the discriminators includes a binarization circuit and a pulse conversion circuit. The binarization circuit changes an output signal from a corresponding one of the light-receiving elements to a rectangular pulse having a predetermined pulse width and outputs the rectangular pulse. The pulse conversion circuit subtracts a predetermined pulse width from a dead time of the light-receiving element to obtain a difference, and reduces the pulse width of the rectangular pulse by the difference to convert the rectangular pulse to the shaped rectangular pulse.

The pulse conversion circuit in each of the discriminators according to the second aspect is preferred to include a delay section and an AND element. The delay section delays the corresponding one of the rectangular pulses by the difference and outputs the delayed pulse as an output pulse. The AND element outputs a logical product of the corresponding one of the rectangular pulses and the output pulse of the delay section.

A third aspect of the present disclosure is a photodetector including an array that includes a plurality of light-receiving elements; a plurality of discriminators that convert output signals from the respective plurality of light-receiving elements to pulsed signals; and an adder circuit that adds up the pulsed signals outputted from the plurality of discriminators and outputs an obtained added-up signal. In the photodetector, each of the discriminators includes a binarization circuit and a pulse conversion circuit. The binarization circuit changes an output signal from a corresponding one of the light-receiving elements to a rectangular pulse and outputs the rectangular pulse. The pulse conversion circuit combines a first pulse having a predetermined pulse width based on a rising edge of the rectangular pulse, with a second pulse having the pulse width based on a falling edge of the rectangular pulse to convert the rectangular pulse to the pulsed signal.

The pulse conversion circuit of each of the discriminators according to the third aspect is preferred to include a first delay section, a second delay section, a third delay section, a first AND element, a second AND element, and an OR element. The first delay section delays the rectangular pulse by a dead time of the light-receiving element and outputs the delayed pulse as an output pulse. The second delay section delays the rectangular pulse by a total of the dead time t_{D} of the light-receiving element and the pulse width and outputs the delayed pulse as an output pulse. The third delay section delays the rectangular pulse by the pulse width and outputs the delayed pulse as an output pulse. The first AND element calculates a logical product of the output pulse outputted from the first delay section and an inverted pulse of the output pulse outputted from the second delay section, and outputs the logical product as the first pulse. The second AND element calculates a logical product of the inverted pulse of the rectangular pulse and the output pulse outputted from the third delay section, and outputs the logical product as the second pulse. The OR element calculates a logical sum of the first pulse outputted from the first AND element and the second pulse outputted from the second AND element, and outputs the logical sum as the pulse signal.

The light-receiving elements are preferred to be avalanche photon diodes used in a Geiger mode.

A fourth aspect of the present disclosure is an optical ranging apparatus including a light source that emits pulsed light to a measurement target, and the photodetector according to any one of the first to third aspects. The apparatus further includes a measuring unit that allows the photodetector to receive pulsed light that is emitted from the light source and returned being reflected by the measurement target, and measures time of flight of the pulsed light from when the pulsed light is emitted from the light source until when the pulsed light is received by the photodetector to measure a distance from the optical ranging apparatus to the measurement target.

### First Embodiment

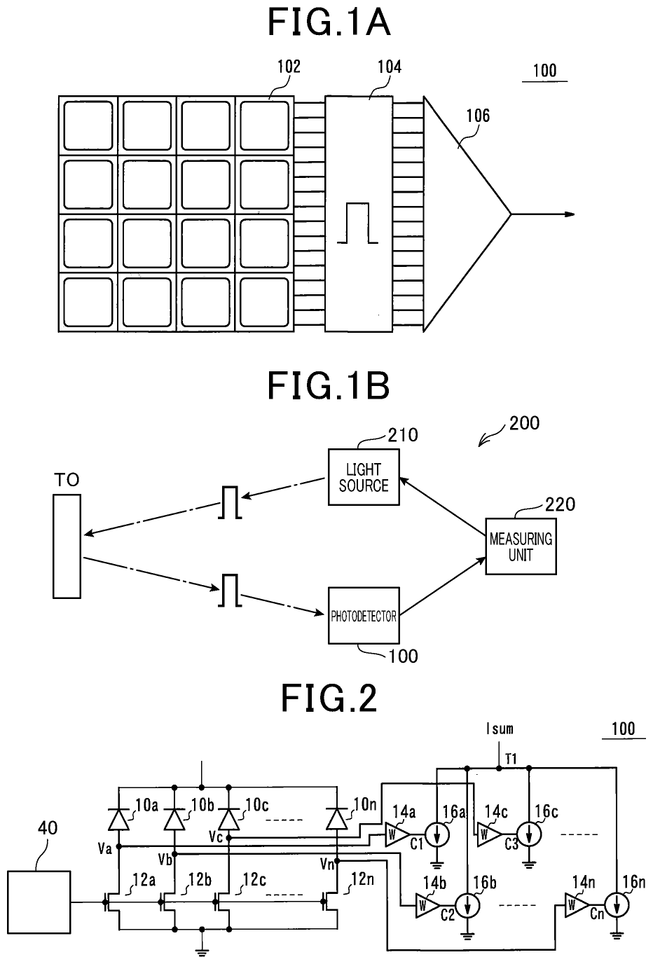

FIG. 1A shows a photodetector 100 that includes a light-receiving unit 102, a discrimination unit 104, and a signal processing unit 106. FIG. 2 shows a specific configuration example of the photodetector 100.

For example, as shown in FIG. 1B, the photodetector 100 can be applied to a light-receiving unit of an optical ranging apparatus 200. Specifically, the optical ranging apparatus 200 includes a light source 210, the photodetector 100, and a measuring unit 220. The light source 210 emits pulsed light, such as a laser pulse, at a time point when instructed by the measuring unit (controller) described below. The photodetector 100 receives the pulsed light emitted from the light source 210 and returned being reflected by a measurement target TO, i.e., receives the pulsed light as returned light. The measuring unit 220 measures time of flight (TOF) of the pulsed light from when it is emitted from the light source 210 at the above time point until when it is received by the photodetector 100 after being reflected by the measurement target TO, and measures a distance to the measurement target from the optical ranging apparatus 200, based on the measured time of flight.

The light-receiving unit 102 includes single photon avalanche photodiodes (SPADs) 10 (10a to 10n) as light-receiving elements arranged in a two-dimensional array, and quenching elements 12 (12a to 12n) respectively connected in series with the SPADs 10 (10a to 10n). The discrimination unit 104 includes discriminators 14 (14a to 14n) corresponding to the SPADs 10 (10a to 10n). The signal processing unit 106 includes current sources 16 (16a to 16n) corresponding to the discriminators 14 (14a to 16n).

In FIG. 1A, light-receiving surfaces are respectively formed by the SPADs 10 (10a to 10n) which are arranged in a two-dimensional array in the light-receiving unit 102 to form an image with photons received by the light-receiving surfaces. Specifically, the SPADs 10 (10a to 10n) individually configure pixels. FIG. 1 shows the case where the number of pixels is n, i.e., the number of SPADs 10 is 16. However, the number of pixels, i.e., the number of SPADs 10, in the present embodiment is not limited to 16.

In the following description, when a signal processed in the photodetector 100 of the first embodiment is at a high level, the signal is taken to be in an active state, and when a signal processed similarly is at a low level, the signal is taken to be in an inactive state. Alternatively, however, as a modification of the first embodiment, when a signal processed is at a low level, the signal may be taken to be in an active state, and when a signal processed is at a high level, the signal may be taken to be in an inactive state. This may achieve advantageous effects similar to those of the first embodiment.

As mentioned above, the light-receiving unit 102 includes the two-dimensionally arrayed SPADs 10a to 10n. The SPADs 10a to 10n are activated in a Geiger mode. Specifically, the SPADs 10a to 10n are activated at a reverse bias voltage that is not less than a breakdown voltage, and each serve as a photo counting light-receiving element that allows an avalanche phenomenon to occur even when a single photon is incident thereon. Accordingly, the light-receiving unit 102 has high sensitivity to incident light such as laser light.

It is preferred that the SPADs 10a to 10a each have a guard ring region or a metal wiring region which is as small as possible, and each have a high fill factor (aperture ratio) that is a percentage of a light-receiving region to an element area. In particular, the fill factors of the respective two-dimensionally arrayed SPADs 10a to 10n can be increased by not forming quenching elements or recharge elements inside the respective SPADs 10a to 10n.

The quenching elements 12 (12a to 12n) can be configured by transistors. The quenching elements 12 (12a to 12n) are preferred to be connected to the respective SPADs 10a to 10n via wires on the outside of the SPADs 10a to 10n.

When photons are incident on the light-receiving unit 102, avalanche current occurs in the SPADs 10a to 10n. The avalanche current raises the voltage between the terminals of each of the quenching elements 12a to 12n connected in series with the respective SPADs 10a to 10n to thereby drop the bias voltage applied to the SPADs 10a to 10n. If the bias voltage drops below the breakdown voltage, the avalanche current stops. The quenching elements 12 (12a to 12n) are also used for generating output voltage applied to the respective discriminators 14 (14a to 14n). Specifically, when a photon is emitted from the light source 210 and is incident on a light-receiving surface after being reflected by the measurement target TO, the corresponding one of the SPADs 10a to 10n is ensured to detect the photon and output an output signal suitable for the detected photon to the corresponding one of the discriminators 14a to 14n.

The photodetector 100 includes a control circuit 40 which turns on/off the quenching elements 12a to 12n to switch the respective SPADs 10a to 10n between a state where an output signal is outputted (on state) and a state where no output signal is outputted (off state), when light is received.

The discriminators 14 (14a to 14n) are provided to respective pairs of the SPADs 10a to 10n and quenching elements 12a to 12n. The following description will be provided, taking the discriminator 14a as an example. Description of the discriminators 14b to 14n, which have configurations and functions similar to those of the discriminator 14a, will be omitted.

The discriminator 14a compares the terminal voltage of the quenching element 12a with a predetermined reference value and generates a rectangular pulse based on the comparison. For example, in the present embodiment, the discriminator 14a generates a shaped rectangular pulse having a shaped (controlled) pulse width. In the present embodiment, when a photon is initially incident on the SPAD 10a, and an output pulse is outputted from the SPAD 10a, the discriminator 14a generates an output signal whose pulse width is reduced by a predetermined length.

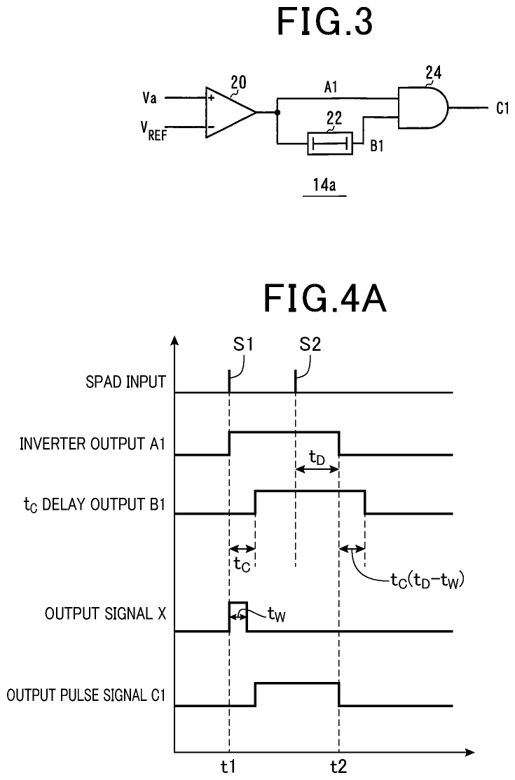

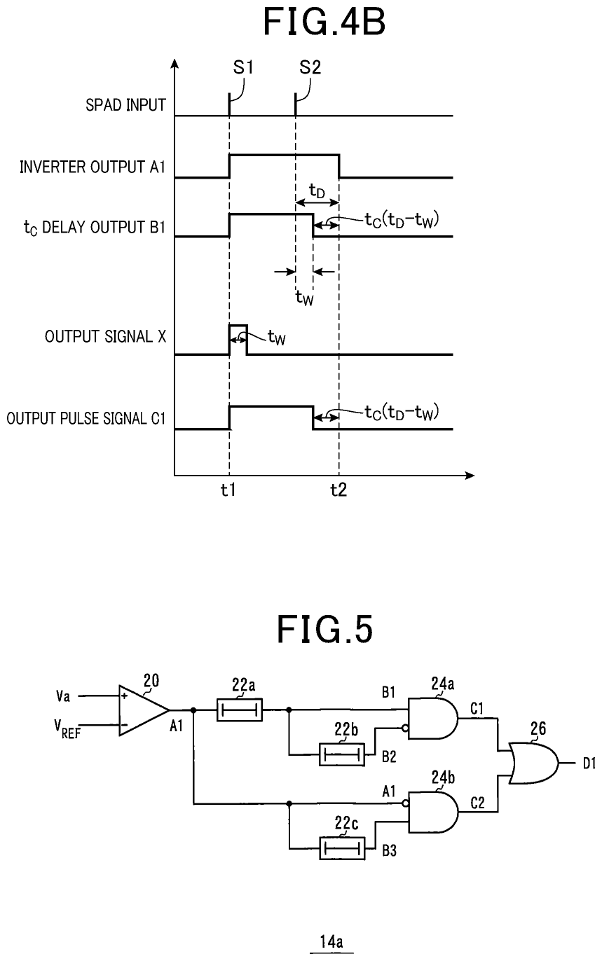

As shown in FIG. 3, the discriminator 14a may have a configuration including an inverter (comparator) 20 serving as the pulse output section, a delay element 22, and an AND element 24. FIG. 4 shows a timing diagram illustrating operation of the discriminator 14a having this configuration.

The inverter 20 compares a terminal voltage Va of the quenching element 12a with a reference voltage V_{REF}. Specifically, as shown in FIG. 4A, when a photon S1 emitted from the light source 210 and reflected by the measurement target TO is incident on the SPAD 10a (see the reference sign S1), the SPAD 10a discharges due to the entry of the photon S1 (this may also be termed firing) to raise the terminal voltage Va of the quenching element 12a to a level of the reference voltage V_{REF} or more and apply an output signal from the SPAD 10a to the inverter 20 (time t1). Consequently, the inverter 20 raises an output pulse A1, i.e., a rectangular pulse, at a predetermined high level because the output signal from the SPAD 10a, i.e., the terminal voltage Va of the quenching element 12a, is at the reference voltage V_{REF} or more (time t1). In the present embodiment, the inverter 20 of the discriminator 14a configures the binarization circuit which outputs an output signal based on the corresponding SPAD 10a and shaped into a rectangular pulse having a predetermined pulse width.

If an incident photon S1 is detected by the SPAD 10a, the SPAD 10a cannot detect light before the lapse of a predetermined dead time t_{D}. In other words, the output signal of the SPAD 10a (terminal voltage Va) is maintained at the reference voltage V_{REF} or more until the lapse of the dead time t_{D}. If the subsequent photon S2 is incident on the SPAD 10a during the dead time t_{D}, the pulse width of the output pulse A1 outputted from the inverter 20 increases exceeding the normal dead time t_{D} and falls down to a predetermined low level at time t2. In the present embodiment, the output pulse A1 rises to a high level due to the arrival of the photon S1. If the subsequent photon S2 is incident during the dead time of the photon S1 (within t_{D}), the output pulse A1 is outputted at a low level after the lapse of the dead time of the photon S2. Specifically, if the photon S2 is incident during the dead time t_{D} of the photon S1, the pulse width of the output pulse A1 will be larger than in the case where there was no entry of the photon S2.

According to the present embodiment, an output pulse A1 from the inverter 20 is inputted to the delay element 22. If an output pulse A1 is inputted from the inverter 20, the delay element 22 delays the change (rise and fall) of the output pulse A1 by a delay time t_{c} and outputs the delayed pulse as an output pulse B1. The delay time t_{c} may favorably be obtained by subtracting a pulse width t_{w} of emitted light of the light source from the dead time t_{D} of the SPAD 10a.

Specifically, if the output of the inverter 20 is an output pulse A1 which is longer than the dead time t_{D} that starts from time t1, it is apparent that the subsequent photon S2 has been incident on the SPAD 10a before the lapse of the dead time t_{D} that precedes the falling time t2 of the output pulse A1. Specifically, as shown in FIG. 4A, the pulse width of the output pulse A1 is longer than the pulse width outputted when the photons S1 and S2 are incident, by a length corresponding to a value obtained by subtracting the pulse width t_{w} from the dead time t_{D}, i.e., t_{c}=(t_{D}−t_{w}).

Thus, the present embodiment includes the delay element 22 and the AND element 24 to reduce the pulse width of the output pulse A1 by a length corresponding to the delay time t_{c}. Specifically, the delay element 22 configures the delay section which delays the output pulse A1 by the length corresponding to a value obtained by subtracting the pulse width t_{w} of the emitted light of the light source from the dead time t_{D}.

The AND element 24 receives inputs of the output pulse A1 of the inverter 20 and the output pulse B1 of the delay element 22. In this case, the AND element 24 calculates a logical product of the inputted output pulses A1 and B1 and outputs an output signal C1 based on the calculated logical product. Specifically, as shown in FIG. 4, the discriminator 14a outputs an output signal C1, i.e., a rectangular pulse which is reduced, relative to the rising edge, by a length corresponding to the delay time t_{c} from the pulse width of the output pulse A1 of the inverter 20 which is based on the output signal of the SPAD 10a. In the present embodiment, the delay element 22 and the AND element 24 configure the pulse conversion circuit.

In particular, the terminal voltage Va, which is an output signal of the SPAD 10a, exhibits steep rise at a time point (t1) when a photon is received by the SPAD 10a. Therefore, in the discriminator 14a of the present embodiment, the output signal C1 is ensured to rise being delayed by the time t_{c} from time t1 when the SPAD 10a receives a photon, i.e., from the time point when an output signal is inputted to the discriminator 14a from the SPAD 10a.

The discriminator 14a is not limited to the configuration shown in FIG. 3, but may be a discriminator that similarly outputs an output signal C1 having a pulse width reduced by the length corresponding to the time t_{c} from the pulse width of the output pulse A1 outputted from the inverter 20. For example, as shown in FIG. 4B, the delay element 22 may be configured as a reduction circuit that outputs an output pulse A1 from the inverter 20 as a pulse B2 which is reduced by the length corresponding to the time t_{c}, so that an output signal C1 outputted from the AND element 24 can be a pulse reduced by the length corresponding to the time t_{c} from the pulse width of the output pulse A1 outputted from the inverter 20.

The discriminators 14b to 14n operate similarly to the discriminator 14a. Consequently, output signals C1 to Cn each having a rectangular pulse are outputted from the respective discriminators 14a to 14n.

When the output signals C1 to Cn each having a rectangular pulse are outputted from the respective discriminators 14 (14a to 14n) and inputted to the respective current sources 16 (16a to 16n) shown in FIG. 2, each of the current sources 16 (16a to 16n) passes current of a predetermined value during a period when the corresponding one of the output signals C1 to Cn having a rectangular pulse is at a high level. The current sources 16 (16a to 16n) are connected to a single output terminal T1 of the signal processing unit 106, so that added-up current Isum obtained by adding up current outputted from the current sources 16 (16a to 16n) passes through the output terminal T1. Thus, the current sources 16 in the signal processing unit 106 configure the adder circuit.

In particular, the present embodiment is characterized in that the added-up current Isum is a value corresponding to the total number of photons substantially simultaneously detected (i.e., within the time t_{w}) by the SPADs 10a to 10n of the light-receiving unit 102. Specifically, the photodetector 100 can accurately detect the number of pulses of light (photons) incident on the SPADs 10a to 10n, based on the value of the added-up current Isum.

Use of the added-up current Isum as a trigger signal can enhance the accuracy of detecting pulsed light reflected by the measurement target. For example, in the present embodiment, if a trigger signal is ensured to be outputted when the added-up current Isum indicates three units (a state where photons are incident on three of the SPADs 10a to 10n) or more, pulsed light reflected by the measurement target can be detected with high accuracy.

As described above, in the photodetector 100 of the present embodiment, when a photon is incident on a SPAD 10a and an output pulse A1, i.e., a rectangular pulse, is outputted from the inverter 20 of the SPAD 10a, the output pulse A1 is converted to a shaped output pulse having a pulse width based on the rising and falling edges of the output pulse A1. Then, the photodetector 100 outputs the shaped output pulse to the corresponding current source 16 as an output signal C1.

Specifically, as shown in FIG. 4A, the output pulse C1, i.e., a rectangular pulse, outputted from the discriminator 14a is configured as an output signal, i.e., a rectangular pulse, which is obtained by reducing the pulse width of the output pulse A1 of the inverter 20 based on the output signal of the SPAD 10a, by the length corresponding to the delay time t_{c} relative to the rising edge. Let us assume herein the case where a first photon S1 is incident on a SPAD 10a, and then a second photon S2 is incident on the SPAD 10a during the dead time t_{D} of the SPAD 10a based on the detection of the first photon S1.

In this case, the output signal, i.e., a rectangular pulse, from the discriminator 14a could be outputted as an output signal X, i.e., a rectangular pulse, having a fixed width (t_{w}) based, for example, on the pulse width t_{w} of the first photon S1 (see FIG. 4A). If this occurs, there would be no output signal from the discriminator 14a at time t2 when the second photon S2 is incident, and therefore the second photon S2 is unlikely to be counted.

In this regard, the photodetector 100 of the present embodiment can change the pulse width of the output signal (rectangular pulse) C1 outputted from the discriminator 14a to a pulse width based on the photons S1 and S2. Accordingly, if a second photon S2 is incident on the SPAD 10a during the dead time t_{D} of the SPAD 10a based on the detection of the first photon S1, the first and second photons S1 and S2 can be correctly counted. Specifically, according to the present embodiment, even when first photons are incident on the respective SPADs 10a to 10an and then second photons are respectively incident thereon during the dead time based on the incidences of the first photons, the number of arrivals of the first and second photons at the SPADs 10a to 10an within the time corresponding to the pulse width t_{w} can be counted with high accuracy.

### Second Embodiment

A photodetector according to a second embodiment of the present disclosure will be described. The photodetector of the second embodiment is different from the photodetector 100 of the first embodiment in the configuration of the discriminators 14a to 14n. The differences will be explained below.

The following description will be provided, taking the discriminator 14a as an example. Description of the discriminators 14b to 14n, which have configurations and functions similar to those of the discriminator 14a, will be omitted. The discriminator 14a of the present embodiment assumes the case where another photon is incident on the SPAD 10a during the dead time t_{D} of the SPAD 10a. In such a case, the discriminator 14a of the present embodiment generates an output signal by combining two pulses with each having a predetermined pulse width, depending on the time when the first photon is incident. The predetermined pulse width is preferred to match the pulse width t_{w} of emitted light of the light source.

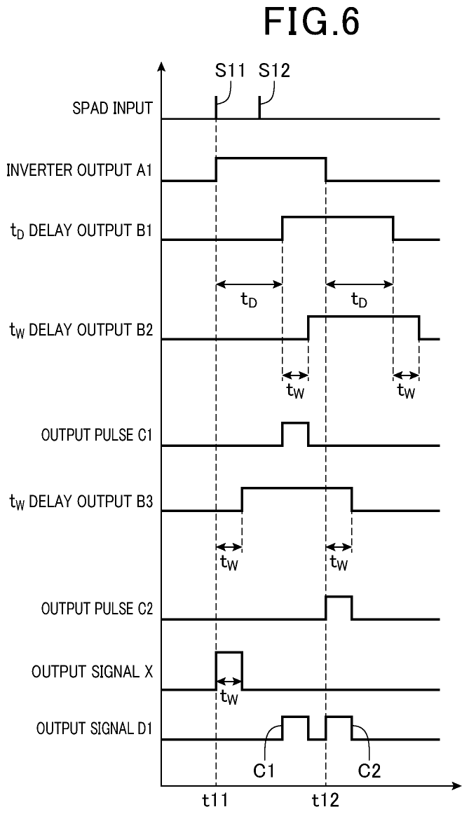

As shown in FIG. 5, the discriminator 14a may have a configuration including an inverter (comparator) 20, a first delay element 22a, a second delay element 22b, a third delay element 2c, a first AND element 24a, a second AND element 24b, and an OR element 26. FIG. 6 a shows a timing diagram illustrating operation of the discriminator 14a having this configuration.

As shown in FIG. 6, when a photon emitted from the light source 210 and reflected by the measurement target TO is incident on the SPAD 10a (see the reference sign S1), the SPAD 10a discharges due to the entry of the photon, resultantly raising the terminal voltage Va of the quenching element 12a to a level of the reference voltage V_{REF} or more and applying an output signal of the SPAD 10a to the inverter 20 (time t11). The inverter 20, when it receives application of the output signal of the SPAD 10a, i.e., the terminal voltage Va of the quenching element 12a, compares the terminal voltage Va with the reference voltage V_{REF} and raises an output pulse A1, i.e., a rectangular pulse, at a high level because the terminal voltage Va is at the reference voltage V_{REF} or more.

In the absence of any incident photon on the SPAD 10a, the terminal voltage Va is less than the reference voltage V_{REF} and thus the inverter 20 maintains the output thereof at a low level.

If an incident photon is detected by the SPAD 10a, the SPAD 10a cannot detect light before the lapse of a predetermined dead time t_{D}. In other words, the output signal of the SPAD 10a (terminal voltage Va) is maintained at the reference voltage V_{REF} or more until the lapse of the dead time t_{D}.

If a subsequent second photon S12 is incident on the SPAD 10a during the dead time t_{D}, the pulse width of the output pulse A1 outputted from the inverter 20 increases exceeding the normal dead time t_{D} and falls down to a predetermined low level at time t12. In the present embodiment, the output pulse A1 rises to a high level due to the arrival of a photon. If the second photon S12 is incident during the dead time of photon (within t_{D}), the output pulse A1 is outputted at a low level after the lapse of the dead time of the photon S12. Specifically, if the photon S12 is incident during the dead time t_{D}, the pulse width of the output pulse A1 will be larger than in the case where there was no entry of the photon S12.

According to the present embodiment, an output pulse A1 from the inverter 20 is inputted to the delay element 22a. If an output pulse A1 is inputted from the inverter 20, the delay element 22a delays the change (rise and fall) of the output pulse A1 by the dead time t_{D} and outputs the delayed pulse as an output pulse B1. In the present embodiment, the delay element 22a configures the first delay section.

If an output pulse B1 is inputted from the delay element 22a, the delay element 22b delays the change (rise and fall) of the output pulse B1 by a delay time t_{w} corresponding to the pulse width t_{w} of emitted light of the light source and outputs the delayed pulse as an output pulse B2. Specifically, the delay elements 22a and 22b delay the change (rise and fall) of the output pulse A1 of the inverter 20 by the time corresponding to the total of the dead time t_{D} and the delay time t_{w} and output the delayed pulse as an output pulse B2. In the present embodiment, the delay elements 22a and 22b configure the second delay section.

Following the input of an output pulse A1 from the inverter 20, the delay element 22c delays the change (rise and fall) of the output pulse A1 by the delay time t_{w} and outputs the delayed pulse as an output pulse B3. In the present embodiment, the delay element 22c configures the third delay section.

Following the input of the output pulse B1 and the input of an inverted pulse of the output pulse B2 from the delay element 22b, the first AND element 24a calculates a logical product of these pulses and outputs the logical product as a first output pulse C1. Specifically, the output pulse B1 is delayed by the dead time t_{D} from time t11 when the first photon S11 is incident, while the output pulse B2 is further delayed from the output pulse B1 by the predetermined pulse width t_{w} of the light source. Therefore, as shown in FIG. 6, the first output pulse C1 based on the logical product of these pulses has the pulse width t_{w} and corresponds to the first photon S11.

Following the input of the inverted pulse of the output pulse A1 from the inverter 20 and the input of the output pulse B3 from the delay element 22c, the first AND element 24a calculates a logical product of these pulses and outputs the logical product as a second output pulse C2. Specifically, the falling edge t12 of the output pulse A1 means an end of the dead time t_{D} of the second photon S12. The second output pulse C2 is based on a logical product of this output pulse A1 and the output pulse B3 which is delayed from the falling edge t12 by the predetermined pulse width t_{w} of the light source. Accordingly, as shown in FIG. 6, the second output pulse C2 has the pulse width t_{w} and corresponds to the second photon S12.

Following the input of the first output pulse C1 from the first AND element 24a and the input of the second output pulse C2 from the second AND element 24b, the OR element 26 calculates a logical sum of these pulses and outputs the logical sum as an output signal D1. In this way, the discriminator 14a outputs the output signal D1 that is a combination of two pulses, i.e., the first and second output pulses C1 and C2, each having a fixed pulse width t_{w}, based on the output pulse A1 of the SPAD 10a. In the present embodiment, the delay elements 22a to 22c, and the first and second AND elements 24a and 24b configure the pulse conversion circuit. The discriminators 14b to 14n function similarly to the discriminator 14a.

In the photodetector of the present embodiment, let us assume as in the first embodiment, the case where a first photon S11 is incident on a SPAD 10a, and then a second photon S12 is incident on the SPAD 10a during the dead time t_{D} of the SPAD 10a based on the detection of the first photon S11.

In this case, the output signal, i.e., a rectangular pulse, from the discriminator 14a could be outputted as an output signal X, i.e., a rectangular pulse, having a fixed width (t_{w}) based, for example, on the pulse width t_{w} of the first photon S11 (see FIG. 6). If this occurs, there would be no output signal from the discriminator 14a at time t12 when the second photon S12 is incident, and therefore the second photon S12 is unlikely to be counted.

In this regard, the photodetector of the present embodiment can convert the output pulse A1 from the inverter 20 into an output signal D1 and output the converted signal. The output signal D1 has two rectangular pulses, i.e., C1 and C2, respectively corresponding to the actual photons S11 and S12 and each having a corresponding pulse width t_{w}. Therefore, even when the second photon S12 is incident on the SPAD 10a during the dead time t_{D} of the SPAD 10a based on the detection of the first photon S11, the first and second photons S11 and S12 can be correctly counted. Specifically, according to the present embodiment, even when first photons are incident on the respective SPADs 10a to 10an and then second photons are respectively incident thereon during the dead time based on the incidences of the first photons, the number of arrivals of the first and second photons at the SPADs 10a to 10an within the time corresponding to the pulse width t_{w} can be counted with high accuracy.

The discriminators 14a to 14n are not limited to the configuration shown in FIG. 5, but may be a discriminator that similarly outputs the output pulse A1 from the inverter 20 as an output signal D1 having two rectangular pulses each having a pulse width t_{w}.

### Comparative Example

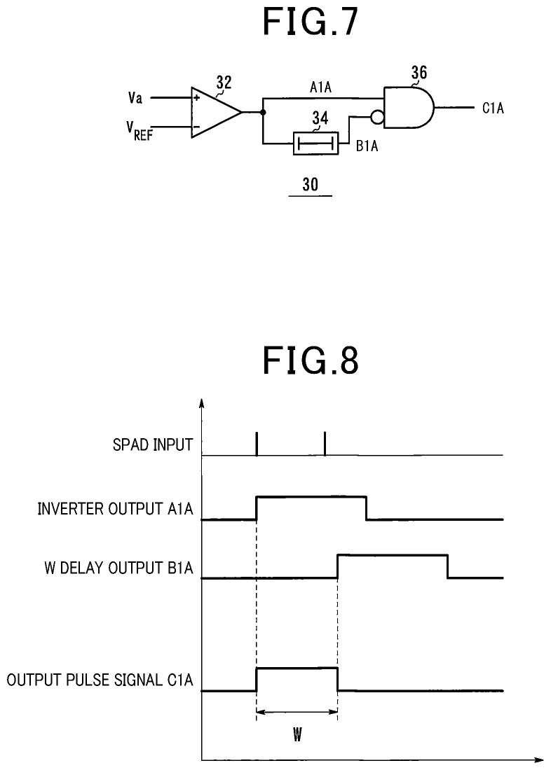

FIG. 7 shows a discriminator 30 according to a comparative example which includes an inverter 32, a delay element 34, and an AND element 36. FIG. 8 shows a timing diagram illustrating operation of the discriminator 30.

The inverter 32, when it receives application of a terminal voltage Va of the quenching element, compares the terminal voltage Va with the reference voltage V_{REF} and outputs an output pulse A1A at a high level if the terminal voltage Va is equal to or more than the reference voltage V_{REF}, or outputs an output pulse A1A at a low level if the terminal voltage Va is less than the reference voltage V_{REF}. The delay element 34, when it receives an input of an output pulse A1A from the inverter 32, delays the change of the output pulse A1A by a delay time W and outputs the delayed pulse as a pulse B1A. The delay time W is, for example, in the range of 1 nanosecond or more and 20 nanoseconds or less. Following the input of the output pulse A1A from the inverter 32 and the input of an inverted signal of the output pulse B1A from the delay element 34, the first AND element 36 calculates and outputs a logical product of them. Thus, the discriminator 30 generates and outputs a rectangular pulse C1A having a pulse width corresponding to the predetermined delay time W, from the time point when the terminal voltage Va, i.e., an output from the SPAD, has reached the level of the reference voltage V_{REF} or more.

### Advantageous Effects of the First and Second Embodiments

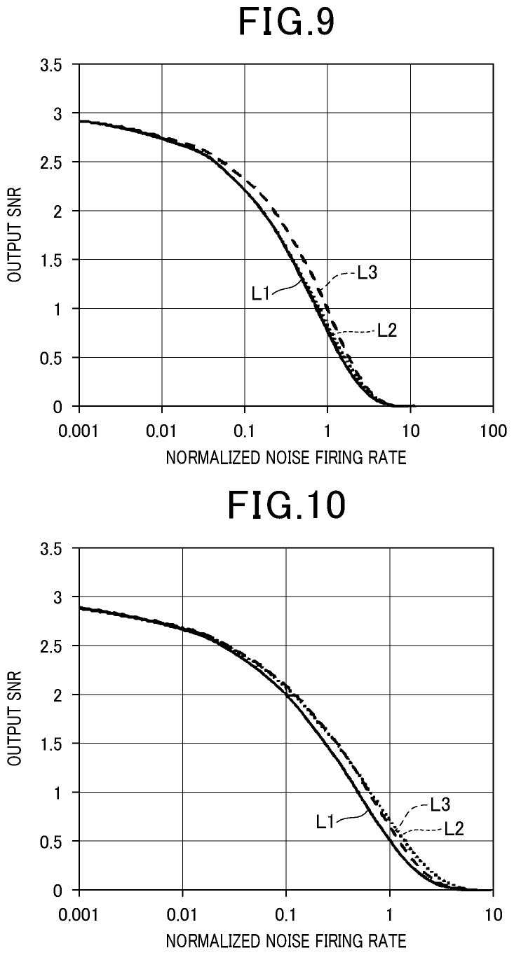

FIGS. 9 and 10 each show simulations for the photodetectors 100 respectively using the discriminators 14 of the first and second embodiments, and the photodetector using the discriminator 30 of the comparative example, in terms of a relationship between signal to noise ratio (SNR) and noise firing rate. In each of FIGS. 9 and 10, the horizontal axis indicates normalized noise firing rate, and the vertical axis indicates signal to noise ratio (SNR) of the output of the photodetectors. The normalized noise firing rate refers to a value obtained by multiplying m_{N} by t_{D} (m_{N}×t_{D}), where m_{N} is an average count [count/s] of reactions of the SPADs 10a to 10n of the light-receiving unit 102 with noise, such as ambient light, and t_{D} is a dead time of the SPADs 10a to 10n.

FIG. 9 shows simulations under conditions where the signal to noise ratio (SNR) of the input signal is 3, and the pulse width t_{w} of emitted light of the light source is ¼ of the dead time t_{D} of the SPAD 10a. FIG. 10 shows simulations under conditions where the signal to noise ratio (SNR) of the input signal is 3, and the pulse width t_{w} of emitted light of the light source is ½ of the dead time t_{D} of the SPAD 10a.

In FIGS. 9 and 10, the solid line L1 indicates a simulation for the photodetector using the discriminator 30 of the comparative example, the dotted line L2 indicates a simulation for the photodetector 100 using the discriminator 14 according to the first embodiment, and the broken line L3 indicates a simulation for the photodetector 100 using the discriminator according to the second embodiment.

As shown in FIGS. 9 and 10, in both of the cases, the signal to noise ratio (SNR) was improved in the photodetectors 100 using the discriminators 14 of the first and second embodiments even more than in the photodetector using the discriminator 30 of the comparative example.

In particular, as shown in FIG. 9, when the pulse width t_{w} of the emitted light was ¼ of the dead time t_{D}, the signal to noise ratio (SNR) of the photodetector 100 using the discriminator 14 of the second embodiment was optimum, irrespective of the normalized noise firing rate. In a region where the normalized noise firing rate exceeded 0.1, the signal to noise ratio (SNR) of the photodetector 100 using the discriminator 14 of the first embodiment was also improved even more than in the discriminator 30 based on the conventional art.

As shown in FIG. 10, when the pulse width t_{w} of the emitted light was ½ of the dead time t_{D}, the signal to noise ratio (SNR) of the photodetectors 100 using the discriminators 14 of the second and first embodiments were good, irrespective of the normalized noise firing rate. In particular, when the normalized noise firing rate exceeded 1.0, the signal to noise ratio (SNR) of the photodetector using the discriminator 14 of the first embodiment was higher than that of the photodetector using the discriminator 14 of the second embodiment in some regions.

As described above, according to the present disclosure, a photodetector 100 capable of correctly counting inputted photons can be provided. Thus, the signal to noise ratio (SNR) of the photodetector 100 can be improved.

What is claimed is:

1. A photodetector comprising:
a pulse output section that outputs an output from a light-receiving element as a first rectangular pulse having a predetermined pulse width; and
a pulse conversion circuit that converts the first rectangular pulse to a second rectangular pulse having a pulse width different from the predetermined pulse width, the second rectangular pulse being based on rise of the first rectangular pulse and fall of the first rectangular pulse.

2. A photodetector comprising:
an array that includes a plurality of light-receiving elements;
a plurality of discriminators that convert output signals from the respective plurality of light-receiving elements to shaped rectangular pulses; and
an adder circuit that adds up the shaped rectangular pulses outputted from the plurality of discriminators and outputs an obtained added-up signal, wherein
each of the discriminators comprises:
a binarization circuit that changes an output signal from a corresponding one of the light-receiving elements to a rectangular pulse having a predetermined pulse width and outputs the rectangular pulse, and
a pulse conversion circuit that subtracts a predetermined pulse width from a dead time of the light-receiving element to obtain a difference, and reduces the pulse width of the rectangular pulse by the difference to convert the rectangular pulse to the shaped rectangular pulse.

3. The photodetector according to claim 2, wherein the pulse conversion circuit in each of the discriminators includes:
a delay section that delays the corresponding one of the rectangular pulses by the difference and outputs the delayed pulse as an output pulse; and
an AND element that outputs a logical product of the corresponding one of the rectangular pulses and the output pulse of the delay section.

4. A photodetector comprising:
an array that includes a plurality of light-receiving elements;
a plurality of discriminators that convert output signals from the respective plurality of light-receiving elements to pulsed signals; and
an adder circuit that adds up the pulsed signals outputted from the plurality of discriminators and outputs an obtained added-up signal, wherein
each of the discriminators comprises:
a binarization circuit that changes an output signal from a corresponding one of the light-receiving elements to a rectangular pulse and outputs the rectangular pulse, and
a pulse conversion circuit that combines a first pulse having a predetermined pulse width based on a rising edge of the rectangular pulse, with a second pulse having the pulse width based on a falling edge of the rectangular pulse to convert the rectangular pulse to the pulsed signal.

5. The photodetector according to claim 4, wherein the pulse conversion circuit of each of the discriminators includes:
a first delay section that delays the rectangular pulse by a dead time of the light-receiving element and outputs the delayed pulse as an output pulse;
a second delay section that delays the rectangular pulse by a total of the dead time t_{D} of the light-receiving element and the pulse width and outputs the delayed pulse as an output pulse;
a third delay section that delays the rectangular pulse by the pulse width and outputs the delayed pulse as an output pulse;
a first AND element that calculates a logical product of the output pulse outputted from the first delay section and an inverted pulse of the output pulse outputted from the second delay section, and outputs the logical product as the first pulse;
a second AND element that calculates a logical product of the inverted pulse of the rectangular pulse and the output pulse outputted from the third delay section, and outputs the logical product as the second pulse; and
an OR element that calculates a logical sum of the first pulse outputted from the first AND element and the second pulse outputted from the second AND element, and outputs the logical sum as the pulse signal.

6. The photodetector according to claim 1, wherein the light-receiving elements are avalanche photon diodes used in a Geiger mode.

7. An optical ranging apparatus comprising:
a light source that emits pulsed light to a measurement target; and
the photodetector according to claim 1, wherein
the apparatus further comprises a measuring unit that allows the photodetector to receive pulsed light that is emitted from the light source and returned being reflected by the measurement target, and measures time of flight of the pulsed light from when the pulsed light is emitted from the light source until when the pulsed light is received by the photodetector to measure a distance from the optical ranging apparatus to the measurement target.

8. The photodetector according to claim 2, wherein the light-receiving elements are avalanche photon diodes used in a Geiger mode.

9. The photodetector according to claim 3, wherein the light-receiving elements are avalanche photon diodes used in a Geiger mode.

10. An optical ranging apparatus comprising:
a light source that emits pulsed light to a measurement target; and
the photodetector according to claim 2, wherein
the apparatus further comprises a measuring unit that allows the photodetector to receive pulsed light that is emitted from the light source and returned being reflected by the measurement target, and measures time of flight of the pulsed light from when the pulsed light is emitted from the light source until when the pulsed light is received by the photodetector to measure a distance from the optical ranging apparatus to the measurement target.

11. An optical ranging apparatus comprising:
a light source that emits pulsed light to a measurement target; and
the photodetector according to claim 4, wherein
the apparatus further comprises a measuring unit that allows the photodetector to receive pulsed light that is emitted from the light source and returned being reflected by the measurement target, and measures time of flight of the pulsed light from when the pulsed light is emitted from the light source until when the pulsed light is received by the photodetector to measure a distance from the optical ranging apparatus to the measurement target.
